(19) United States
(12) Patent Application Publication
(10) Pub. No.: US 2008/0245294 A1
(43) Pub. Date: Oct. 9, 2008

(54) RACK

(75) Inventors: Anthony R. Horelik, Farmington, CT (US); Michael B. Hogan, Simsbury, CT (US); David F. Macdonald, Suffield, CT (US)

Correspondence Address: HOFFMANN & BARON, LLP, 6900 JERICHO TURNPIKE, SYOSSET, NY, 11791, US

(73) Assignee: HENKEL CORPORATION, Rocky Hill, CT (US)

(21) Appl. No.: 11/697,376

(22) Filed: Apr. 6, 2007

(51) Int. Cl. C23C 14/00

(52) U.S. Cl. 118/50

(57) ABSTRACT

The subject invention is directed to a rack for supporting at least one article during a vacuum impregnation process with the article having treated and untreated surfaces. The rack includes a metallic body defining at least one nest for accommodating the article, the nest being configured to support the article under vacuum impregnation conditions. Also, non-metallic bearing surfaces are disposed on portions of the nest. The bearing surfaces are configured to contiguously contact the treated surfaces of the article during the vacuum impregnation process with contiguous contact between the treated surfaces of the article and the metallic body being avoided. Advantageously, with the subject invention, a metallic rack may be utilized which avoids damage to the treated surfaces of an article undergoing vacuum impregnation.

### BACKGROUND OF THE INVENTION

This invention is directed to racks for impregnation processes, more particularly, to metallic racks for impregnation processes.

Metallic articles may be formed by casting or by sintering powdered metal. Such processes are commonly used with aluminum, magnesium, brass, bronze, grey cast iron, zinc and various steels to form housings and other components which will be required to retain or conduct a fluid medium. These articles may include: automotive components, such as engine blocks, cylinder heads, valves, pump housings, gearboxes, fittings, and vehicle brake components; high pressure system components; hydraulic/pneumatic valves and fittings; and, pumps and pump components. With a casting or sintering process, however, articles are formed porous and not fluid tight.

Processes have been developed in the prior art to seal a cast or sintered article using plastic resins. One such process is a vacuum impregnation process, wherein the cast or sintered article is subjected to vacuum to evacuate air from the open pores. The article is then exposed to a liquid uncured resin, optionally with pressure being applied, so as to fill the open pores. Typically, the resin is anaerobic or heat curable. Subsequent curing results in an article having its pores fully impregnated with cured resin, which provides a sealed, fluid-tight structure.

Vacuum impregnation processes are typically conducted iteratively at multiple stations. To accommodate a plurality of articles, and to permit transportation of the articles from station to station, the articles may be mounted to racks. The racks may retain the articles during the entirety of the vacuum impregnation process.

Racks for vacuum impregnation have been formed in the prior art of metal, e.g., stainless steel, or from plastic. Metal racks often cause scratching or other damage under vacuum impregnation conditions to the articles undergoing vacuum impregnation. This is particularly undesired at treated (e.g., machined) surfaces of the articles which are intended to be sealing surfaces for mating with other articles or fixtures (e.g., a sealing face of a flange). The treated surfaces may be machined or chemically treated surfaces which have a surface finish different from the untreated cast or sintered surface, particularly a surface of enhanced smoothness suitable for defining a sealing surface. For example, a housing may be worked oil which includes a mounting flange having a machine treated surface intended to seal against a secondary flange. Any gouging or scratching of the treated flange surface may be a threat to cause leakage and render the article as unusable. Plastic racks avoid causing damage to the corresponding articles. However, plastic racks react differently to vacuum impregnation conditions than metal racks, requiring much greater amounts of resin (e.g., 30-50% more resin) and increased water usage during the washing stages, as compared to metal racks under similar conditions. In addition, plastic racks have shorter life cycles than metal racks.

### SUMMARY OF THE INVENTION

The subject invention is directed to a rack for supporting at least one article during a vacuum impregnation process with the article having treated and untreated surfaces. The rack includes a metallic body defining at least one nest for accommodating the article, the nest being configured to support the article under vacuum impregnation conditions. Also, non-metallic bearing surfaces are disposed on portions of the nest. The bearing surfaces are configured to contiguously contact the treated surfaces of the article during the vacuum impregnation process with contiguous contact between the treated surfaces of the article and the metallic body being avoided. Advantageously, with the subject invention, a metallic rack may be utilized which avoids damage to the treated surfaces of an article undergoing vacuum impregnation.

These and other features of the invention will be better understood through a study of the following detailed description and accompanying drawings.

### BRIEF DESCRIPTION OF THE DRAWINGS

FIG. 1 is a schematic depicting a vacuum impregnation process;

FIG. 2 is a top plan view of a rack formed in accordance with the subject invention;

FIG. 3 is a schematic side view of the rack shown in FIG. 2;

FIG. 4 is an elevational view of a nest usable with the subject invention;

FIG. 5 depicts a nest accommodating an article having treated and untreated surfaces; and

FIG. 6 is a top plan view of a non-metallic bearing surfaces usable with the subject invention.

### DETAILED DESCRIPTION OF THE INVENTION

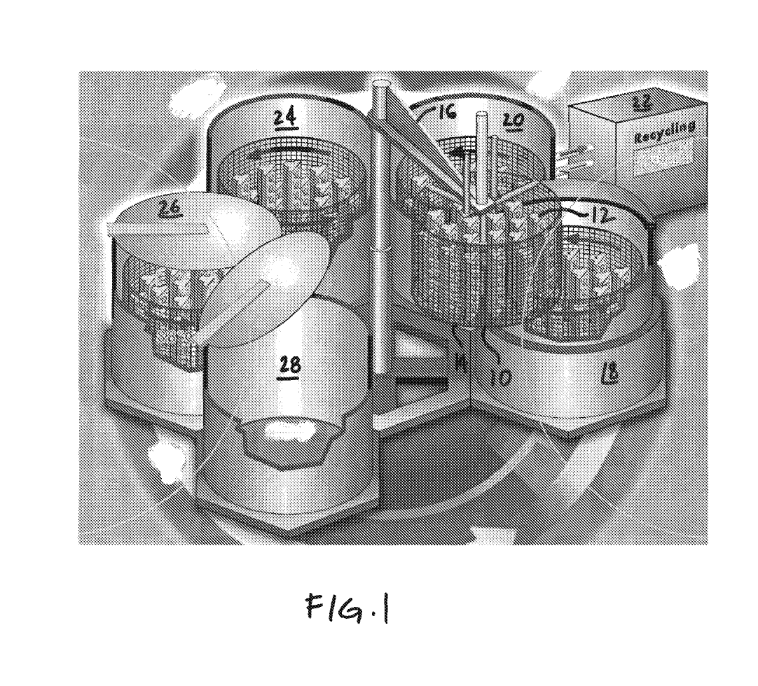

A rack 10 is provided which may be used to accommodate one or more articles 12 during various impregnation processes, including dry vacuum-pressure processes, wet vacuum/pressure processes, wet vacuum processes and pressure impregnation processes. By way of illustration and non-limiting example, FIG. 1 depicts schematically a vacuum impregnation process. As will be readily recognized by those skilled in the art, the rack 10 may be used with various impregnation processes, particularly vacuum impregnation processes.

With reference to FIG. 1, an impregnation process may be conducted over a series of working steps conducted at the same or different locations. The process in FIG. 1 shows various working steps being conducted at different stations. Initially, one or more of the articles 12 are loaded onto the rack 10. The rack 10 is, in turn, loaded into a basket 14. The basket 14 may be configured to accommodate a plurality of the racks 10 loaded with the articles 12 in a stacked arrangement. Once loaded, the basket 14 may be transported by any known means, including the use of a moving crane 16. The loaded basket 14 is initially placed into a first work station 18. Depending on the particular impregnation process, the first work station 18 may be initially flooded with uncured resin (for a wet vacuum process) or be without resin (for a dry process). With the loaded basket 14 secured in the first work station 18, vacuum may be applied which either acts directly on the articles 12 or indirectly on the articles 12 through the uncured resin. The vacuum acts to remove air from pores in the articles 12.

After application of vacuum, the first work station 18 may be filled with uncured resin, if dry vacuum was initially applied. With the articles 12 being submerged in uncured resin, the uncured resin may be pressurized to enhance the impregnation effect (e.g., dry vacuum/pressure impregnation; wet vacuum/pressure impregnation) of the uncured resin into the pores of the articles 12. During pressurization and/or filling of the first work station 18 with uncured resin, the first work station 18 may be vented to atmosphere. Alternatively, the first work station 18 may be vented to atmosphere without increased pressure being generated after the vacuum stage, particularly after a wet vacuum stage. Applied vacuum alone can be relied on to cause impregnation of the uncured resin within the pores of the articles 12 (e.g., wet vacuum impregnation).

The resin typically will be a heat curable resin or an anaerobically curable resin. Examples of usable heat curable resins include methacrylates or polyesters that can be cured at temperatures below the boiling point of water, including, but not limited to resins sold under the trademarks “RESINOL 90C”, “LOCTITE RESINOL 88C”, and “LOCTITE RESINOL 90R” by Henkel Corporation of Madison Heights, Mich. With an anaerobically curable resin, the resin will start immediately curing in the pores of the articles 12 to the extent there is no exposure to oxygen. Examples of usable anaerobic resins include methacrylate sealants which self-cure in the absence of air, including, but not limited to, resins sold under the trademarks “LOCTITE PMS-50E”, “LOCTITE RESINOL RTC”, “LOCTITE RESINOL AT”, “LOCTITE 5120” and “LOCTITE 990” by Henkel Corporation of Madison Heights, Mich.

After the resin is applied to the articles 12, the basket 14 may be centrifuged in the first work station 18 to permit excess resin to be removed and returned to the primary supply of uncured resin to be reused.

The basket 14 may be then moved by the crane 16 to a second work station 20 which is a wash station. For washing, the articles 12 are preferably subjected to agitated movement under water, with up and down and rotational movement. Compressed air may be introduced to enhance the agitation effect. Water from the washing process may be sent to a recycling station 22 for extraction of any recovered resin. After washing, the water may be drained from the second work station 20, and the basket 14 may be centrifuged.

The remainder of the impregnation process may be varied to accommodate the particular curing characteristics of the used resin, e.g., heat curable or anaerobically curable resins. With anaerobically curable resins, the basket 14 may be transported to a third work station 24 at which a rinse process is conducted. The rinse solution may optionally include a catalyst to enhance the curing of the resin. After rinsing, the basket 14 may be transported to a fourth work station 26, where the articles 12 are washed with heated water (e.g., water at 110° F. (43° C.)) which permits any remaining catalyst to be removed. In addition, a corrosion inhibitor may be applied. Optionally, the basket 14 may be centrifuged to quicken the drying process after washing is completed. Once completed, the basket 14 is removed, as shown representatively by empty fourth work station 28, with the articles 12 being fully impregnated and fluid tight.

With a heat curable resin, the basket 14 may be introduced into a subsequent work station with heated water, such as the fourth work station 26, after the second work station 20. The articles 12 are desirably allowed to soak in heated water (e.g., 194° F. (90° C.)) for a sufficient period of time to permit full curing. Optionally, the basket 14 may be centrifuged after soaking. Once completed, the basket 14 is removed with the articles 12 being fully impregnated and fluid tight.

As will be readily appreciated by those skilled in the art, various impregnation processes may be utilized with the subject invention. The processes described herein are for illustrative purposes and are in no way limiting of the invention.

With reference to FIG. 2, a possible configuration of the rack 10 is depicted. The rack 10 includes a body 30 preferably having interstices 32 formed therein to permit resin and other fluids (e.g., wash water; rinse water; catalysts) to pass therethrough. The body 30 may be formed of various dimensions and shapes depending on various factors, such as the intended number of the articles 12 to be accommodated, the shape of the basket 14, and/or the shape of the work stations 18, 20, 24, 26.

The body 30 is preferably metallic and formed to withstand repeated uses under vacuum impregnation conditions. By way of non-limiting example, the body 30 nay be formed as a wire mesh body being defined by a plurality of joined metal wires 34. The body 30 may be formed of any metal, but is preferably formed of a corrosion-resistant metal, such as stainless steel.

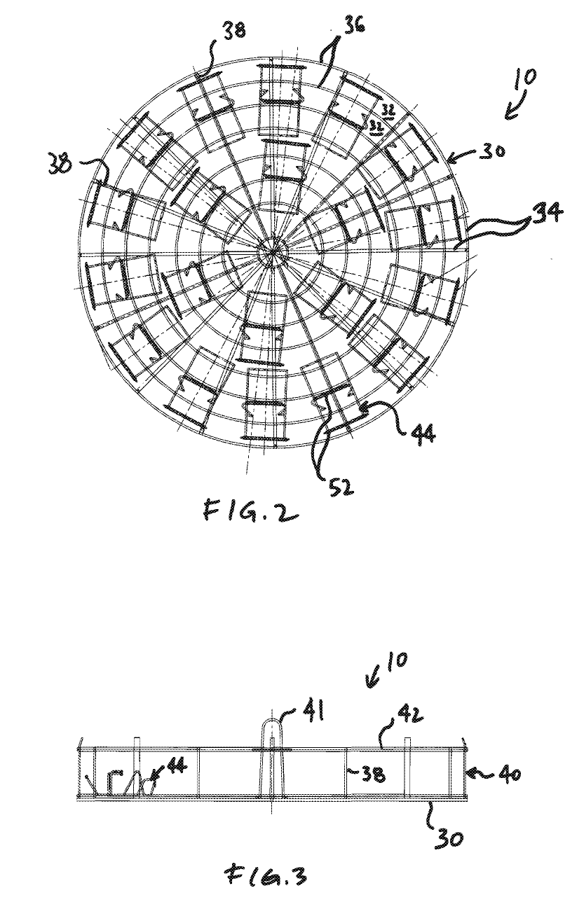

As shown in FIG. 2, the wires 34 may be arranged with concentric wires 36 being supported by truss wires 38 which radiate from the center of the body 30. The truss wires 38 may extend upwardly, as shown in FIG. 3, to define a sidewall 40 for the rack 10. To provide stability to the sidewall 40, one or more hoop wires 42 can be disposed about the periphery thereof. The wires 34 may also be bent to define a handle 41 or other feature which facilitates handling of the rack 10.

The rack 10 may also include one or more nests 44 for accommodating the articles 12. The nests 44 are configured to accommodate the articles 12, particularly to support the articles 12 under vacuum impregnation conditions. The nests 44 may be of various shapes and dimensions arranged to accommodate the articles 12. The nests 44 are preferably formed to support the articles 12 under various working phases of vacuum impregnation processes, including: application of vacuum; transportation from point to point; washing or rinsing; application of elevated pressure; and/or, elevated temperatures. It is preferred that the nests 44 support the articles 12 during all forms of movement (e.g., up, down, sideways, rotational) and prevent relative movement between the rack 10 and the articles 12.

Preferably, each of the nests 44 is configured to accommodate one of the articles 12. The nests 44 may be provided in any quantity on the rack 10 and may be identically or differently formed to accommodate the same or different of the articles 12. FIG. 3 depicts one of the nests 44 being on the body 30.

By way of non-limiting example, the nests 44 may be formed from wires 46 bent and arranged to accommodate the articles 12. As shown in FIGS. 2-4, the wires 46 may define portions 48 for connecting the nests 44 to the body 30 using any known technique, such as welding, bonding and so forth. Alternatively, the nests 44 may be formed, in whole or in part, integrally with the body 30, such as being defined by the wires 34.

The nests 44 may each include transverse members 48, which, for example, may be defined by one or more of the wires 46, for limiting relative movement of the articles 12 relative to the body 30. The nests 44 may also include one or more moveable elements 50 which are selectively moveable between an article receiving position (shown in dashed lines in FIG. 4) and an article retaining position (shown in solid lines in FIG. 4). The wires 46 are preferably metallic, more preferably of a corrosion-resistant metal, such as stainless steel.

With reference to FIG. 2, non-metallic bearing surfaces 52 may be disposed on portions of the nests 44, including the moveable element 50. The non-metallic bearing surfaces 52 are configured to contiguously contact treated surfaces of the articles 12 during the vacuum impregnation process. As shown in FIG. 5, the non-metallic bearing surfaces 52 contiguously contact treated surface 54 of the article 12. The treated surface 54 may be a machined and/or chemically treated surface which has improved surface characteristics (e.g. better smoothness) as compared to untreated surfaces 56 of the article 12. Preferably, with this arrangement, contiguous contact between the body 30, including the nests 44, and the treated surfaces 54 is avoided, with the only contiguous contact being permitted between the treated surfaces 54 and the non-metallic bearing surfaces 52. The body 30, including the nests 44, and exposed metal portions thereof may contiguously contact the untreated surfaces 56. For example, the transverse members 48 may contiguously contact the untreated surfaces 56 in providing support for the articles 12.

With the subject invention, damage (e.g., scratching, gouging) to the treated surface 54 may be avoided with the article 12 undergoing vacuum impregnation. As such, the usability of the article 12 is not affected. The untreated surfaces 56 may suffer some scratching, gouging or other damage; however, such damage will generally not affect the usability of the article 12 and be acceptable.

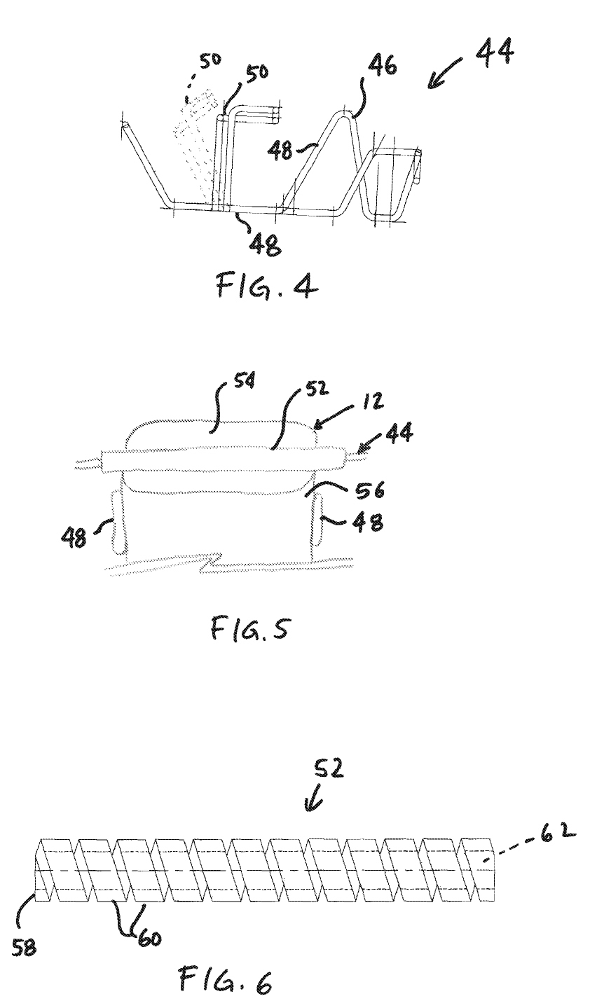

The non-metallic bearing surfaces 52 may be formed of various non-metallic materials, preferably a polymeric (e.g., polyurethane) and/or elastomeric material. The non-metallic bearing surfaces 52 may also be formed with various shapes and be continuous (FIG. 5) or discontinuous. With reference to FIG. 6, a possible configuration for the non-metallic bearing surfaces 52 is shown which includes a coiled body 58 having spaced-apart windings 60 and an inner lumen 62. The coiled body 58 may be securely mounted to one or more of the wires 46 forming the nests 44, for example with one or more of the wires 46 passing through the lumen 62.

What is claimed is:

1. A rack for supporting at least one article during a vacuum impregnation process, the article having treated and untreated surfaces, said rack comprising:
a metallic body defining at least one nest for accommodating the article, said nest being configured to support the article under vacuum impregnation conditions; and,
non-metallic bearing surfaces disposed on portions of said nest, said bearing surfaces configured to contiguously contact the treated surfaces of the article during the vacuum impregnation process with contiguous contact between the treated surfaces of the article and said metallic body being avoided.

2. A rack as in claim 1, wherein said bearing surfaces comprise a polymeric material.

3. A rack as in claim 1, wherein said bearing surfaces comprise an elastomeric material.

4. A rack as in claim 1, wherein said bearing surfaces are discontinuous.

5. A rack as in claim 1, wherein said bearing surfaces are continuous.

6. A rack as in claim 1, wherein said nest is configured to selectively retain the article so as to generally prevent relative movement between the article and said metallic body.

7. A rack as in claim 1, wherein said nest includes transverse members for limiting relative movement between the article and said metallic body.

8. A rack as in claim 7, wherein said transverse members are metallic and configured to contiguously contact the untreated surfaces of the article.

9. A rack as in claim 1, wherein said nest includes at least one moveable element for selectively moving between an article receiving position, where the article may be inserted into said nest, and a retaining position, where said moveable element is positioned to retain the article in said nest.

10. A rack as in claim 9, wherein at least a portion of said bearing surfaces are disposed on said moveable element.

11. A rack as in claim 1, wherein the article is a metallic cast article.

12. A rack as in claim 1, wherein the treated surfaces are selected from the group consisting of machined surfaces, chemically treated surfaces, and combinations thereof.
